(19) United States
(12) Patent Application Publication
(10) Pub. No.: US 2025/0326066 A1
(43) Pub. Date: Oct. 23, 2025

(54) LASER PROCESSING APPARATUS

(71) Applicant: DISCO CORPORATION, Tokyo (JP)

(72) Inventors: Naotoshi KIRIHARA, Tokyo (JP); Ryugo OBA, Tokyo (JP)

(21) Appl. No.: 19/169,466

(22) Filed: Apr. 3, 2025

(30) Foreign Application Priority Data
Apr. 23, 2024 (JP) 2024-069555

(51) Int. Cl. B23K 26/38; B23K 26/06; B23K 26/0622; B23K 26/067; B23K 101/34; B23K 103/00

(52) U.S. Cl. CPC B23K 26/38; B23K 26/0622; B23K 26/0643; B23K 26/0665; B23K 26/067; B23K 26/0648; B23K 2101/34; B23K 2103/50

(57) ABSTRACT

The processing apparatus includes a holding means that holds a wafer; a laser beam applying unit that applies a pulsed laser beam onto the wafer held on the holding means; and process-feeding means that process-feeds the holding means and the laser beam applying unit relative to each other. The laser beam applying unit includes an oscillator that oscillates a pulsed laser beam; a splitting portion that splits the pulsed laser beam, oscillated by the oscillator, into a first optical path and a second optical path; a first condenser that is disposed on the first optical path and condenses the pulsed laser beam onto the wafer; a wavelength converter that is disposed on the second optical path and converts a wavelength of the pulsed laser beam oscillated by the oscillator; and a second condenser that condenses a pulsed laser beam, generated after the wavelength is converted, onto the wafer.

### BACKGROUND OF THE INVENTION

### 1. Field of the Invention

The present invention relates to a laser processing apparatus which applies a pulsed laser beam onto a wafer.

### 2. Description of the Related Art

A wafer, where a plurality of devices such as ICs and LSIs are formed on the front face, and demarcated by projected dicing lines, is diced into individual device chips by a dicing apparatus and a laser processing apparatus, and the device chips are used in electric appliances, such as portable phones and personal computers.

In a case where a low dielectric constant insulation film (Low-k film) is layered on the surface of the wafer, a problem is that if the wafer is cut using a cutting blade, the Low-k film may peel off like mica, and this peeling may reach from the projected dicing line to a device, dropping the quality of the device.

To solve the above problem, the applicant of the present invention has proposed a technique in which two lines of grooves are formed on both sides of the projected dicing line by applying a laser beam, and the devices are cut between these two lines of grooves using a cutting blade, so that peeling of the insulation film does not reach the device, even if the projected dicing line is cut by the cutting blade (see JP 2005-064230 A).

### SUMMARY OF THE INVENTION

However if the Low-k film (e.g. 10 μm thickness) is formed by layering a transparent film, including an SiO2 film, on a silicon substrate, a leaked light of the laser beam causes the peeling at the interface between the Low-k film and the silicon substrate, which drops the quality of individual devices diced from the wafer. As a result, improvement is demanded.

Further, if the two line of grooves are formed on both sides of each projected dicing line by applying the laser beam, the Low-k film remains in a region between these two lines of grooves. Therefore if the projected dicing line is cut by the cutting blade, the cutting in the width direction becomes unstable, and frequent cutting cannot be performed. A solution is to completely remove the Low-k film in the region between the two lines of grooves by applying the laser beam. But in this case, the wavelength of the laser beam appropriate for forming the two lines of grooves and the wavelength of the laser beam appropriate for removing the Low-k film in the region between the two lines of grooves are different, and two units of laser processing apparatuses, of which wavelengths are different, are needed, which is wasteful.

With the foregoing in view, it is an object of the present invention to provide a processing apparatus that can solve such a problem where the generation of peeling at the interface between the Low-k film and the silicon substrate drops the quality of the individual devices diced from the water, by suppressing the leaked light of the laser beam, even if the Low-k film (e.g. 10 μm thickness) is formed on the silicon substrate by layering a transport film, including an SiO2 film. It is also an object of the present invention to provide a processing apparatus that can appropriately form two lines of grooves, and remove the Low-k film in a region between the two lines of grooves using one laser processing apparatus, whereby a problem of the wasteful preparing of two laser processing apparatuses, of which wavelengths are different, can be solved.

To solve the above technical problem, the present invention provides a laser processing apparatus including: holding means that holds a wafer; a laser beam applying unit that applies a pulsed laser beam onto the wafer held on the holding means; and process-feeding means that process-feeds the holding means and the laser beam applying unit relative to each other. The laser beam applying unit includes: an oscillator that oscillates a pulsed laser beam; a splitting portion that splits the pulsed laser beam, oscillated by the oscillator, into a first optical path and a second optical path; a first condenser that is disposed on the first optical path, and condenses the pulsed laser beam onto the wafer held on the holding means; a wavelength converter that is disposed on the second optical path, and converts a wavelength of the pulsed laser beam oscillated by the oscillator; and a second condenser that condenses a pulsed laser beam, generated after the wavelength is converted, onto the wafer held on the holding means.

It is preferable that the wavelength converter converts the wavelength of the pulsed laser beam oscillated by the oscillator into a pulsed laser beam having a wavelength of a deep ultraviolet light, and a value of repetition frequency of the pulsed laser beam oscillated by the oscillator is set to a value at which the pulsed laser beam, having a wavelength of the deep ultraviolet light, is applied onto the wafer at time intervals that are shorter than the thermal diffusion time in a transparent film, including an SiO2 film, layered on an upper face of a silicon substrate. It is also preferable that in a case where the processing feeding direction is an X axis direction, a separating portion that separates a spot of the pulsed laser beam, generated after the wavelength is converted, into two spots in a Y axis direction intersecting orthogonally with the X axis direction, and a beam expander, that adjusts an interval of the spots separated by the separating portion, are disposed on the second optical path. Further, it is preferable that a beam width setting portion, that sets a beam width of the pulsed laser beam in the Y axis direction, is disposed on the first optical path between the splitting portion and the first condenser, so that the beam width of the pulsed laser beam is set corresponding to the interval of the two spots separated by the separating portion.

It is preferable that the splitting portion is constituted of a ½ wave plate and a polarizing beam splitter, and adjusts a ratio of power of a pulsed laser beam guided to the first optical path and guided to the second optical path by rotating the ½ wave plate. The splitting portion may be constituted of a mirror portion and positioning means that positions the mirror portion at an action position or a non-action position, so as to guide the pulsed laser beam to the second optical path by positioning the mirror port at the action position, or guide the pulsed laser beam to the first optical path by positioning the mirror portion at the non-action portion. Further, a beam expander may be disposed between the oscillator and the splitting portion, so that load applied to the splitting portion is reduced by decreasing power density of the pulsed laser beam. The first condenser and the second condenser may be configured by a common condenser. Furthermore, it is preferable that a value of repetition frequency of the pulsed laser beam oscillated by the oscillator is set to a value exceeding 1 MHZ, so that the time interval to apply the pulsed laser beam becomes less than 1.0 μs, which is a thermal diffusion time in an SiO2 film. It is preferable that a wavelength of the pulsed laser beam oscillated by the oscillator is 515 to 532 nm, and a wavelength after being converted by the wavelength converter is 257 to 266 nm.

The laser processing apparatus of the present invention includes: a holding means that holds a wafer; laser beam applying unit that applies a pulsed laser beam onto the wafer held on the holding means; and process-feeding means that process-feeds the holding means and the laser beam applying unit related to each other. The laser beam applying unit includes: an oscillator that oscillates a pulsed laser beam; a splitting portion that splits the pulsed laser beam, oscillated by the oscillator, into a first optical path and a second optical path; a first condenser that is disposed on the first optical path, and condenses the pulsed laser beam onto the wafer held on the holding mean; a wavelength converter that is disposed on the second optical path, and converts a wavelength of the pulsed laser beam oscillated by the oscillator; and a second condenser that condenses a pulsed laser beam, generated after the wavelength is converted, onto the wafer held on the holding means. Therefore, even if a Low-k film (e.g. 10 μm thickness) is formed on a silicon substrate by layering a transparent film, including an SiO2 film, for example, such a problem where the generation of peeling at the interface between the Low-k film and the silicon substrate, which drops the quality of the individual devices diced from the wafer, can be solved by suppressing the leaked light of the laser beam. This also allows to appropriately form the two lines of grooves and remove the Low-k film in a region between the two lines of grooves using one laser processing apparatus, whereby a problem of the wasteful preparing of two laser processing apparatuses having different wavelengths, of which wavelengths are different, can be solved.

### BRIEF DESCRIPTION OF THE DRAWINGS

FIG. 1 is a general perspective view of a laser processing apparatus of the present embodiment;

FIG. 2 is a block diagram depicting a configuration of an optical system of laser beam applying unit disposed in the laser processing apparatus in FIG. 1;

FIG. 3A is a perspective view illustrating a state where the laser processing apparatus in FIG. 1 is performing laser processing to form two lines of grooves onto the wafer, FIG. 3B is a partially enlarged cross-sectional view illustrating a state where the two lines of grooves are formed by the laser processing in FIG. 3A, and FIG. 3C is a plan view illustrating the two lines of grooves in FIG. 3B; and

FIG. 4A is a perspective view illustrating a state where the laser processing apparatus in FIG. 1 is performing laser processing to remove the Low-k film between the two lines of grooves, FIG. 4B is a partially enlarged cross-sectional view illustrating a state where a removed region is formed by the laser processing in FIG. 4A, and FIG. 4C is a plan view illustrating the removed region in FIG. 4B.

### DESCRIPTION OF THE PREFERRED EMBODIMENTS

An embodiment of the processing apparatus configured on the basis of the present invention will be described in detail with reference to the accompanying drawings.

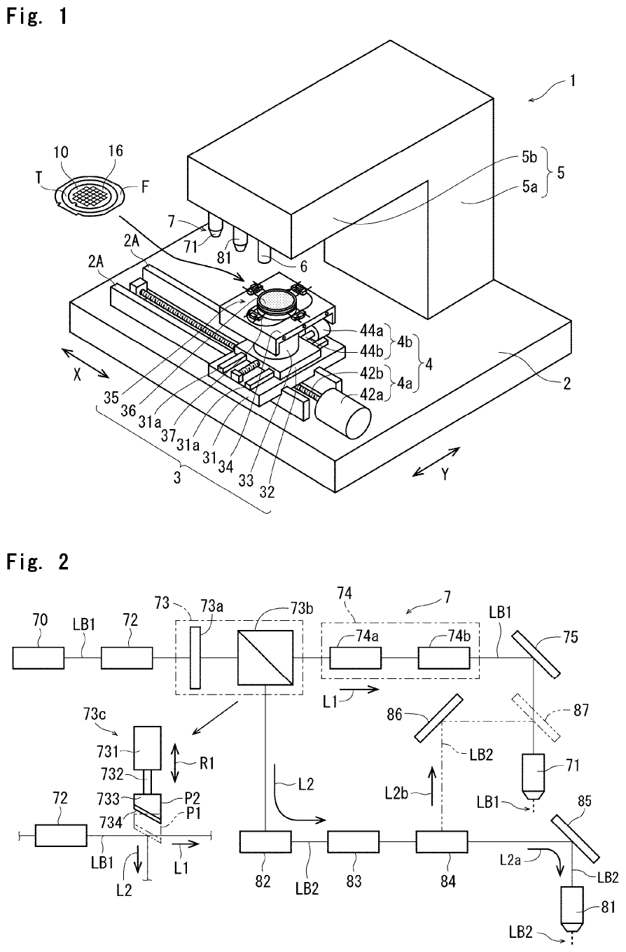

FIG. 1 is an illustration of a laser processing apparatus 1 of this embodiment. Using this laser processing apparatus 1, laser processing is performed on a wafer 10, which is held on an annular-shaped frame F via a protection tape T, as illustrated in FIG. 1. The wafer 10 is a wafer where a Low-k film 16 is formed on an upper face of a silicon substrate by layering a transparent film, including an SiO2 film.

The laser processing apparatus 1 includes: holding means 3 that holds a wafer 10; laser beam applying unit 7 that applies a laser beam onto the wafer 10 held on the holding means 3; and process-feeding means 4 that process-feeds the holding means 3 and the laser beam applying unit 7 in an X axis direction.

In addition to this configuration, the laser processing apparatus 1 of this embodiment includes: alignment means 6 that executes alignment by imaging the wafer 10 held on the holding means 3; a frame 5 constituted of a vertical wall portion 5a which stands on the side of the process-feeding means 4, and a horizontal wall portion 5b which extends from the upper part of the vertical wall portion 5a in the horizontal direction; and control means (not illustrated) that controls each operation portion.

The holding means 3 is means for holding the wafer 10 on a holding surface, which is an XY plane specified by an X coordinate and a Y coordinate, and as illustrated in FIG. 1, the holding means 3 includes: an X axis direction movable plate 31, which is rectangular, and is disposed on a base 2 so as to be movable in the X axis direction; a Y axis direction movable plate 32, which is rectangular, and is disposed on the X axis direction movable plate 31 so as to be movable in the Y axis direction; a support 33, which is cylindrical, and is fixed to an upper face of the Y axis direction movable plate 32; and a cover plate 34, which is rectangular, is fixed to the upper end of the support 33. A chuck table 35, which is extended upward through a long hole formed in the cover plate 34, is disposed on the cover plate 34. The chuck table 35 is rotatably configured by a rotational driving means (not illustrated) housed inside the support 33. A circular suction chuck 36, which is formed of a porous material having air permeability and of which holding surface is an XY plane specified by the X coordinate and the Y coordinate, is disposed on the upper face of the chuck table 35. The suction chuck 36 is connected to suction means (not illustrated) via a passage passing through the support 33, and four clamps 37, which hold the frame F when the wafer 10 is held on the chuck table 35, are disposed around the suction chuck 36 at equal intervals.

The process-feeding means 4 includes: X axis moving means 4a that moves the holding means 3 in the X axis direction; and Y axis moving means 4b that moves the holding means 3 in the Y axis direction. The X axis moving means 4a converts the rotational motion of a motor 42a into linear motion via a ball screw 42b, transfers the linear motion to the X axis direction movable plate 31, and moves the X axis direction movable plate 31 in the X axis direction along a pair of guide rails 2A and 2A, which are disposed on the base 2 along the X axis direction. The Y axis moving means 4b converts the rotational motion of a motor 44a into linear motion via a ball screw 44b, transfers the linear motion to the Y axis direction movable plate 32, and moves the Y axis direction movable plate 32 in the Y axis direction along a pair of guide rails 31a and 31a, which are disposed on the X axis direction movable plate 31 along the Y axis direction.

Inside the horizontal wall portion 5b of the frame 5, the optical system and the alignment means 6, which constitute the above mentioned laser beam applying unit 7, are housed. A first condenser 71 constituting a part of the laser beam applying unit 7, and a second condenser 81 which is adjacent to the first condenser 71 in the X axis direction (indicated by the arrow X in FIG. 1) are disposed on the lower face side of the front end of the horizontal wall portion 5b (described in detail later). The alignment means 6 is imaging means, that captures an image of a wafer 10 which is held on the chuck table 35 of the holding means 3, and detects a position and orientation of the wafer 10, a laser processing position to which the laser beam is applied, and the like. The alignment means 6 is disposed at a position adjacent to the above mentioned first condenser 71 and second condenser 81 in the X axis direction.

FIG. 2 is a block diagram depicting a general configuration of an optical system of the laser beam applying unit 7 based on the present invention. The laser beam applying unit 7 includes: an oscillator 70 that oscillates a pulsed laser beam LB1 having a predetermined wavelength and repetition frequency; a splitting portion 73 which splits the pulsed laser beam LB1 oscillated by the oscillator 70 into a first optical path L1 and a second optical path L2; the first condenser 71 that is disposed on the first optical path L1 and condenses the pulsed laser beam LB1 onto the wafer 10 held on the holding means 3; a wavelength converter 82 that is disposed on the second optical path L2, and converts a wavelength of the pulsed laser beam LB1 oscillated by the oscillator 70; and the second condenser 81 that condenses a pulsed laser beam LB2, generated after the wavelength is converted by the wavelength converter 82, onto the wafer 10 held on the holding means 3.

The splitting portion 73 is constituted of a ½ wave plate 73a and a polarizing beam splitter 73b. By rotating the ½ wave plate 73a and appropriately adjusting a rotation angle of the ½ wave plate 73a, a ratio of power of p-polarized light which transmits through the polarizing beam splitter 73b and is guided to the first optical path L1, and s-polarized light which is reflected by the polarizing beam splitter and is guided to the second optical path L2, can be adjusted.

The wavelength converter 82 disposed on the second optical path L2, for example, converts the wavelength of the pulsed laser beam LB1 oscillated by the oscillator 70 into the pulsed laser beam LB2 having a different wavelength. Specifically, in a case where the pulsed laser beam LB1 oscillated by the oscillator 70 is a green light having a 515 to 532 nm wavelength, the wavelength converter 82 converts this light into a deep ultraviolet light having a 257 to 266 nm wavelength. The wavelength converter 82 is constituted of BBO crystals or CLBO crystals, for example.

The value of the repetition frequency of the pulsed laser beam LB1 oscillated by the oscillator 70 is set to a value to apply the pulsed laser beam LB1 at time intervals that are shorter than the thermal diffusion time in a transparent film, including an SiO2 film, constituting the Low-k film 16 layered on the upper face of the silicon substrate constituting the wafer 10. Specifically, the Low-k film 16 layered on the upper face of the wafer 10 is formed by layering the transparent film, including SiO2 film. The thermal diffusion time of SiO2 is 1.0 μs, hence to prevent peeling at the interface of the Low-k film 16 and the silicon substrate, the repetition frequency is set to a value exceeding 1 MHZ, which is a repetition frequency at which the pulse intervals of the pulsed laser beam applied onto the Low-k film 16 becomes shorter than the thermal diffusion time. It was confirmed that peeling of the Low-k film 16 is more effectively suppressed when the pulse intervals of the laser beam LB1 became less than 1.0 μs, which is the thermal diffusion time in the SiO2 film, and the pulse intervals of the pulsed laser beam LB1 oscillated by the oscillator 70 is preferably set to less than 0.5 μs, and is even more preferably set to less than 0.25 μs. In other words, the repetition frequency of the pulsed laser beam LB1 is preferably set to a value higher than 2 MHZ, and is more preferably set to a value higher than 4 MHZ.

The laser beam applying unit 7 of this embodiment will be described in detail with reference to FIG. 2. A beam expander 72 is disposed between the oscillator 70 and the splitting portion 73. The beam expander 72 can decrease the power density by adjusting a spot diameter of the pulsed laser beam LB1, so as to decrease the load applied to the splitting portion 73.

In a case where the processing feeding direction of the wafer 10 held on the chuck table 35 is the X axis direction, a separating portion 83, that separates a spot of the pulsed laser beam LB2, generated after the wavelength is converted by the wavelength converter 82, into two spots in the Y axis direction, and a beam expander 84 that adjusts the interval of the spots separated by the separating portion 83 in the Y axis direction, are disposed on the second optical path L2. For the separating portion 83, it is preferable to use a birefringent beam splitter, for example.

Between the splitting portion 73 and the first condenser 71 on the first optical path L1, a beam width setting portion 74, that sets a beam width of the pulsed laser beam LB1 in the Y axis direction, is disposed, and sets the beam width of the pulsed laser beam LB1 corresponding to the interval between the two spots separated by the separating portion 83 on the second optical path L2. The beam width setting portion 74 is constituted of a beam expander 74a and a cylindrical lens 74b. The beam expander 74a is used to adjust a spot diameter of the pulsed laser beam LB1, and the cylindrical lens 74b is used to adjust the beam width of the pulsed laser beam LB1. The beam width setting portion 74 may be mask means having an opening which corresponds to an interval of the two spots separated by the separating portion 83.

Besides the above configuration, an attenuator may be disposed on the first optical path L1 and the second optical path L2 respectively, so that output of the pulsed laser beam LB1 and output of the pulsed laser beam LB2, spit by the splitting portion 73, are adjusted independently. Further, on the first optical path L1 and the second optical path L2, reflection mirrors 75 and 85, which guide the pulsed laser beam LB1 and the pulsed laser beam LB2 to the first condenser 71 and the second condenser 81 respectively, for example, may be disposed.

Control means (not illustrated) is constituted of a computer, and includes: a central processing unit (CPU) that performs arithmetic processing according to a control program; a read only memory (ROM) that stores a control program and the like; a random access memory (RAM) that temporarily stores detected values, arithmetic operation results, and the like by allowing reading or writing such data; an input interface; and an output interface (detailed illustrations are omitted). Each operation unit of the laser processing apparatus 1 described above is controlled by this control means.

The laser processing apparatus 1 of this embodiment includes the above mentioned configuration, and the laser processing performed by the laser processing apparatus 1 will now be described.

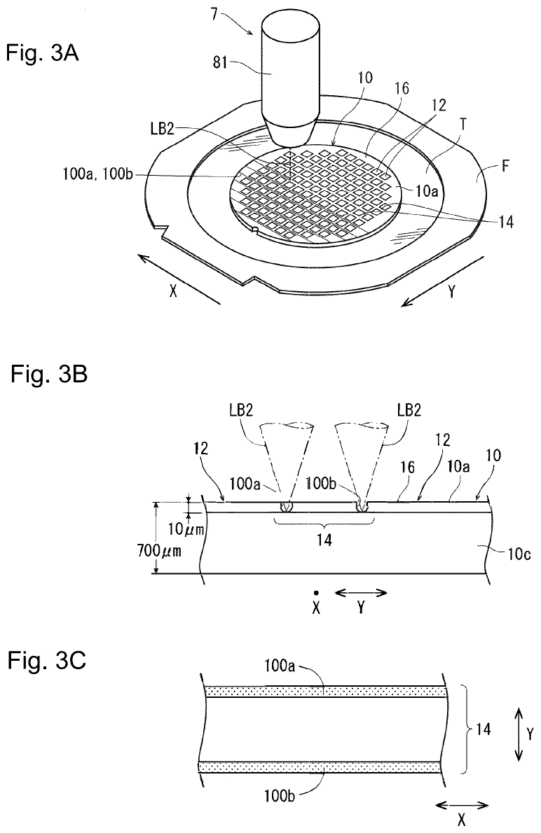

The wafer 10 that is processed on the basis of this embodiment is supported on an annular-shaped frame F via an protection tape T, as shown in FIG. 3A. The wafer 10 is a wafer where a plurality of devices 12, demarcated by the projected dicing lines 14, are demarcated on the front face 10a, and the Low-k film 16 formed by layering the SiO2 film disposed on an upper face of the silicon substrate. The thickness of the Low-k film 16 is 10 μm, for example, and the total thickness of the wafer 10 is 700 μm (the actual dimensional ratio is not used in this example, for convenience of description).

When laser processing is performed on this wafer 10, the wafer 10 is conveyed to the laser processing apparatus 1 (described with reference to FIG. 1), is sucked and held on the chuck table 35 of the holding means 3, and the frame F is fixed by the clamp 37. Then the wafer 10 held on the holding means 3 is conveyed to the position directly under the alignment means 6 by the process-feeding means 4, and is imaged, thereby the positions of the projected dicing lines 14 formed on the front face 10a are detected, and the chuck table 35 is rotated by the rotational driving means, so as to align the projected dicing lines 14 in a predetermined direction on the wafer 10 with the X axis direction. The detected position information on the projected dicing lines 14 is stored in the control means mentioned above.

On the basis of the positional information detected by the alignment means 6, the second condenser 81 of the laser beam applying unit 7 is positioned at a predetermined processing start position of the projected dicing lines 14 aligned in the X axis direction. In the laser processing of this embodiment, two lines of grooves are formed along each side of projected dicing line 14 in the Y axis direction. For this, as illustrated in FIG. 3A, the pulsed laser beam LB2, of which wavelength was converted to the wavelength of deep ultraviolet light (e.g. 266 nm), is applied onto the second optical path L2 of the laser beam applying unit 7. The pulsed laser beam LB2 is constituted of two spots, so as to have a predetermined interval in the Y axis direction, within the width of the projected dicing line 14, and is applied such that the focusing point of the pulsed laser beam LB2 is positioned on each side of the projected dicing line 14 formed on the front face 10a of the wafer 10, as illustrated in FIG. 3B. Here the X axis moving means 4a is activated, and process-feeds the wafer 10 together with the holding means 3 in the X axis direction indicated by the arrow X in FIG. 3A. As a result, as illustrated in FIGS. 3B and 3C, each of the two lines of grooves 100a and 100b is formed on each side of the projected dicing line 14.

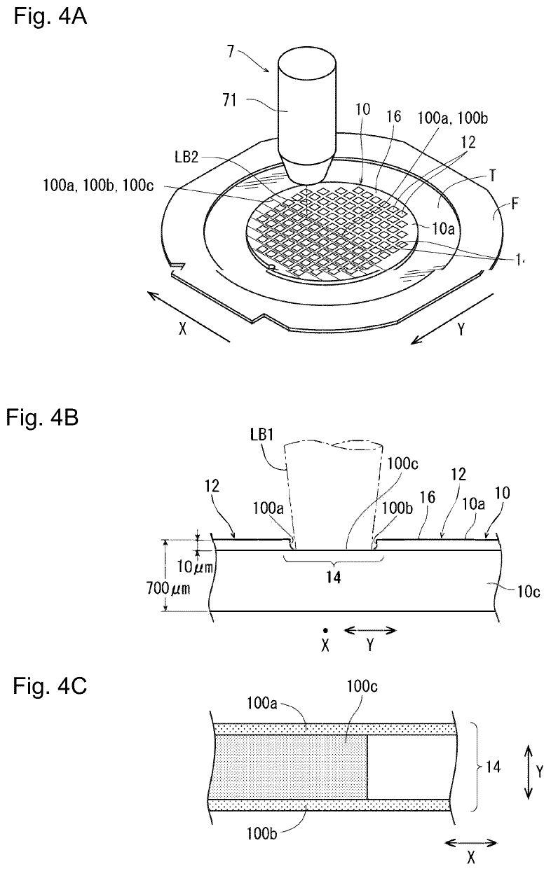

As described above, in the laser beam applying unit 7 of this embodiment, the beam width setting portion 74 is disposed on the first optical path L1, and the beam width of the pulsed laser beam LB1 is formed corresponding to the interval of the two spots of the pulsed laser beam LB2 separated by the separating portion 83 on the second optical path L2. Then in the projected dicing line 14 where two lines of grooves 100a and 100b are formed, the pulsed laser beam LB1 having a wavelength oscillated by the oscillator 70 (e.g. 532 nm) is applied from the first condenser 71, with positioning the focusing point at the center of the two lines of grooves 100a and 100b, so as to follow the pulsed laser beam LB2 which is applied first. Then as illustrated in FIGS. 4B and 4C, the Low-k film 16 remaining between the two lines of grooves 100a and 100b is removed, whereby a removed region 100c is formed. In FIG. 4A, the second condenser 81 is omitted, but the second condenser 81 is actually disposed adjacent to the first condenser 71 in the X axis direction, so that the removed region 100c can be formed in a predetermined projected dicing line 14, following the formation of the two lines of grooves 100a and 100b.

After forming two lines of grooves 100a and 100b, along each side of the predetermined projected dicing line 14 on the wafer 10, the Low-k film 16 remaining between the two lines of grooves 100a and 100b is removed, whereby the removed region 100c is formed. Then the wafer 10 is indexed and fed in the Y axis direction indicated by the arrow Y in FIGS. 4A to 3C, so as to align the adjacent unprocessed projected dicing line 14 in the Y axis direction to a position directly under the second condenser 81. Then the wafer 10 is processed and fed in the X axis direction based on the same procedure described above, whereby the above mentioned grooves 100a and 100b and the removed region 100c are formed. In the same manner, the wafer 10 is processed and fed in the X axis direction and Y axis direction, and the grooves 100a and 100b and the removed region 100c are formed along all projected dicing lines 14 along the X axis direction.

Then the wafer 10 is rotated 90°, so as to align the unprocessed projected dicing lines 14 in a direction intersecting orthogonally to the projected dicing lines 14, for which the grooves 100a and 100b and the removed region 100c have already been formed, with the X axis direction. Then the laser processing is also performed for each of the remaining projected dicing lines 14 based on the same procedure as above, and the two lines of grooves 100a and 100b and the removed region 100c are formed along all projected dicing lines 14 formed on the front face 10a of the wafer 10.

The laser processing conditions to perform the laser processing of this embodiment are set as follows.
Wavelength: pulsed laser beam LB1=532 nm pulsed laser beam LB2=266 nm
Repetition frequency: 4 MHZ
Average output: 0.8 W
Pulse width: 200 fs
Process-feeding speed: 400 mm/s
Condensing lens numerical aperture (NA): 0.068

The power ratio for the splitting portion 73 to split the pulsed laser beam LB1 is set in accordance with the surface area of the processing region when the two lines of grooves 100a and 100b are formed, and the surface area of the processing region when the removed region 100c is formed. In this embodiment, the ratio of the pulsed laser beam LB1 split toward the second optical path L2, where the two lines of grooves 100a a nd 100b are formed, is set to low (e.g. 30%), and the ratio of the pulsed laser beam LB1 split toward the first optical path L1, where the removed region 100c is formed, is set to high (e.g. 70%).

According to the above mentioned embodiment, even if the Low-k film 16 (e.g. 10 μm thickness) is formed by layering the transparent film, including the SiO2 film, the wavelength converter 82 can convert the pulsed laser beam LB1 to the pulsed laser beam LB2 having a desired wavelength. Therefore the split pulsed laser beam LB1 can be converted to the pulsed laser beam LB2 having the wavelength of the deep ultraviolet light by the wavelength converter 82, whereby the leaked light generated upon forming the two lines of grooves 100a and 100b can be suppressed, and the problem of peeling, which is generated at the interface between the Low-k film 16 and the silicon substrate during laser processing, can be solved. Further, the wavelength of the pulsed laser beam LB1 oscillated by the oscillator 70 can be corresponded to the wavelength suitable for removing the Low-k film 16 remaining in the region between the two lines of grooves, and using one laser processing apparatus 1, the two lines of grooves 100a and 100b can be formed, and the Low-k film 16 remaining between the two lines of grooves 100a and 100b can be efficiently removed.

The present invention is not limited to the above embodiment. For example, the above mentioned splitting portion 73 includes the ½ wave plate 73a and the polarizing beam splitter 73b, but a splitting portion 73c, illustrated on the left side of FIG. 2, may be disposed, instead of the ½ wave plate 73a and the polarizing beam splitter 73b. The splitting portion 73c includes a mirror portion 733 and positioning means 731. The mirror portion 733 includes a reflection surface 734. The positioning means 731 includes an elevating rod 732, and the mirror portion 733 is attached to the front end of the elevating rod 732. The elevating rod 732 can be raised or lowered in the direction indicated by the arrow R1 by activating the positioning means 731. If this splitting portion 73c is used, the mirror portion 733 can be positioned at an action position P1 to guide the pulsed laser beam LB1 oscillated by the oscillator 70 to the second optical path L2, or at a non-action position P2 to guide the pulsed laser beam LB2 to the first optical path L1.

In the case of disposing this splitting portion 73c in the laser beam applying unit 7, instead of the above mentioned splitting portion 73, and performing the laser processing thereby, the positioning means 731 is activated so that the mirror portion 733 is moved to the action position P1, and the pulsed laser beam LB1 is reflected on the reflection surface 734 of the mirror portion 733 to guide the pulsed laser beam LB1 to the second optical path L2. Further, the pulsed laser beam LB2, of which wavelength has been converted to the wavelength of the deep ultraviolet light by the wavelength converter 82, is separated into two spots using the separating portion 83, the focusing points of this pulsed laser beam LB2 are positioned in the width direction of the projected dicing line 14 on the wafer 10, then the pulsed laser beam LB2 is applied from the second condenser 81. Thereby, as described with reference to FIGS. 3A to 3C, the two lines of grooves 100a and 100b are formed on the projected dicing line 14 formed on the front face 10a of the wafer 10. Then the positioning means 731 is activated so that the mirror portion 733 is positioned at the non-action position P2, and the pulsed laser beam LB1 is guided to the first optical path L1. Further, the laser processing is performed from the first condenser 71, in a state where the focusing point of the pulsed laser beam LB1, of which beam width in the Y axis direction is set to correspond to the interval of the above mentioned two spots, (that is, the interval of the two lines of grooves 100a and 100b), is positioned at the center of the projected dicing lines 14 of the wafer 10. Then, as described with reference to FIGS. 4A to 4C, the Low-k film 16 remaining between the two lines of grooves 100a and 100b is removed, whereby the removed region 100c is formed. In the case of using the splitting portion 73c to perform the laser processing, it is preferable to dispose an attenuator on the first optical path L1 and the second optical path L2 respectively, so that the output of the pulsed laser beam LB2 to form the two lines of grooves 100a and 100b, and the output of the pulsed laser beam LB1 to form the removed region 100c, can be adjusted independently.

In the embodiment described above, the first condenser 71 and the second condenser 81 are disposed as independent condensers, but are not limited to independent condenser, and one condenser may be used for both the first condenser 71 and the second condenser 81. For example, on the second optical path L2 illustrated in FIG. 2, an optical path L2b, including the reflection mirrors 86 and 87, to guide the pulsed laser beam LB2 from the beam expander 84 to the first condenser 71, is disposed, instead of the optical path L2a from the beam expander 84 to the second condenser 81, then the first condenser 71 can also function as the second condenser 81 described above. In the case of this configuration, the pulsed laser beam LB2, having the two spots generated by the second optical path L2, precedes the spot position of the pulsed laser beam LB1 guided by the first optical path L1 (e.g. 1 mm), and the pulsed laser beam LB1, of which width is set to be wide by the first optical path L1, is applied between the two lines of grooves 100a and 100b, following the pulsed laser beam LB2, of which wavelength was converted to the wavelength of the deep ultraviolet light (266 nm), forming the two lines of grooves 100a and 100b on the projected dicing lines 14 of the wafer 10. Thereby the removed region 100c described with reference to FIGS. 4A to 4C can be formed. By this configuration as well, the Low-k film 16 formed by layering the transparent film, including the SiO2 film, can be appropriately removed from the projected dicing lines 14, just like the embodiment previously described.

In the embodiment described above, the separating portion 83 is disposed on the second optical path L2, and the spot of the pulsed laser beam LB2, of which wavelength has been converted, is separated into two spots in the Y axis direction, so that the two lines of grooves 100a and 100b are simultaneously formed on the projected dicing line 14, but this separating portion 83 may be omitted. In the case where the laser beam applying unit 7 does not include the separating portion 83, the splitting portion of the present invention is configured by the above mentioned splitting portion 73c, and the splitting portion 73c is set as the action position, so that the pulsed laser beam LB1, oscillated by the oscillator 70, is guided to the second optical path L2. Then by the same procedure as the case of the second condenser 81, positioning one spot on one side of the projected dicing line 14 in the width direction, the laser processing is performed to form the groove 100a, then the other spot is positioned on the other side of the projected dicing line 14 in the width direction, and the laser processing is performed to form the groove 100b. Then the splitting portion 73c is set as the non-action position, and the pulsed laser beam LB1, oscillated by the oscillator 70, is guided to the first optical path L1, and the pulsed laser beam LB1 is applied between the grooves 100a and 100b from the first condenser 71, so as to form the removed region 100c. By this configuration and processing procedure as well, the Low-k film 16, formed by layering the transport film, including the SiO2 film, can be appropriately removed from the projected dicing lines 14, just like the case of the embodiment previously described.

### Reference Signs List

1 Laser processing apparatus
2 Base
3 Holding means
35 Chuck table
4 Process-feeding means
4a X axis feeding means
4b Y axis feeding means
5 Frame
6 Alignment means
7 Laser beam applying unit
70 Oscillator
71 First condenser
72 Beam expander
73 Splitting portion
73a ½ wave plate
73b Polarizing beam splitter
74 Beam width setting portion
74a Beam expander
74b Cylindrical lens
75 Reflection mirror
81 Second condenser
82 Wavelength converter
83 Separating portion
84 Beam expander
85 Reflection mirror
10 Wafer
12 Device
14 Projected dicing line
16 Low-k film
100a, 100b groove
100c Removed region
L1 First optical path
L2 Second optical path
LB1, LB2 Pulsed laser beam

What is claimed is:

1. A laser processing apparatus, comprising:
holding means that holds a wafer; laser beam applying unit that applies a pulsed laser beam onto the wafer held on the holding means; and process-feeding means that process-feeds the holding means and the laser beam applying unit relative to each other, wherein
the laser beam applying unit includes:
an oscillator that oscillates the pulsed laser beam; a splitting portion that splits the pulsed laser beam oscillated by the oscillator, into a first optical path and a second optical path; a first condenser that is disposed on the first optical path, and condenses the pulsed laser beam onto the wafer held on the holding means; a wavelength converter that is disposed on the second optical path, and converts a wavelength of the pulsed laser beam oscillated by the oscillator; and a second condenser that condenses a pulsed laser beam, generated after the wavelength is converted, onto the wafer held on the holding means.

2. The laser processing apparatus of claim 1, wherein
the wavelength converter converts the wavelength of the pulsed laser beam oscillated by the oscillator into a pulsed laser beam having a wavelength of a deep ultraviolet light, and
a value of repetition frequency of the pulsed laser beam oscillated by the oscillator is set to a value at which the pulsed laser beam having the wavelength of the deep ultraviolet light is applied onto the wafer at time intervals shorter than thermal diffusion time in a transparent film including a SiO2 film layered on an upper face of a silicon substrate.

3. The laser processing apparatus of claim 1, wherein
in a case where the process-feeding direction is an X axis direction, a separating portion that separates a spot of a pulsed laser beam, generated after the wavelength is converted, into two spots in a Y axis direction intersecting orthogonally with the X axis direction, and a beam expander that adjusts an interval of the spots, separated by the separating portion, are disposed on the second optical path.

4. The laser processing apparatus of claim 3, wherein
a beam width setting portion that sets a beam width of the pulsed laser beam in the Y axis direction is disposed on the first optical path between the splitting portion and the first condenser, so that the beam width of the pulsed laser beam is set corresponding to the interval of the two spots separated by the separating portion.

5. The laser processing apparatus of claim 1, wherein
the splitting portion is constituted of a ½ wave plate and a polarizing beam splitter, and adjusts a ratio of power of a pulsed laser beam guided to the first optical path and that guides the second optical path by rotating the ½ wave plate.

6. The laser processing apparatus of claim 1, wherein
the splitting portion is constituted of a mirror portion and positioning means that positions the mirror portion at an action position or a non-action position, so as to guide the pulsed laser beam to the second optical path by positioning the mirror portion at the action position, or guide the pulsed laser beam to the first optical path by positioning the mirror portion at the non-action position.

7. The laser processing apparatus of claim 1, wherein
a beam expander is disposed between the oscillator and the splitting portion, so that load applied to the splitting portion is reduced by decreasing power density of the pulsed laser beam.

8. The laser processing apparatus of claim 1, wherein
the first condenser and the second condenser are configured by a common condenser.

9. The laser processing apparatus of claim 2, wherein
a value of repetition frequency of the pulsed laser beam oscillated by the oscillator is set to a value exceeding 1 MHz, so that time intervals to apply the pulsed laser beam become less than 1.0 μs, which is a thermal diffusion time of an SiO2 film.

10. The laser processing apparatus of claim 1, wherein
a wavelength of the pulsed laser beam oscillated by the oscillator is 515 to 532 nm, and a wavelength after being converted by the wavelength converter is 257 to 266 nm.
